(19) United States
(12) Patent Application Publication
(10) Pub. No.: US 2026/0018506 A1
(43) Pub. Date: Jan. 15, 2026

(54) SEMICONDUCTOR DEVICE WITH CAPACITOR STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Kun-Yen LIAO, Hsinchu (TW); Ming-Hsien LIN, Hsinchu (TW); Chia-Tien WU, Hsinchu (TW)

(73) Assignee: TAIWAN SEMICONDUCTOR MANUFACTURING COMPANY, LTD., Hsinchu (TW)

(21) Appl. No.: 18/768,494

(22) Filed: Jul. 10, 2024

(51) Int. Cl. H01L 23/522

(52) U.S. Cl. CPC H01L 23/5223; H01L 23/5226; H01L 23/5228; H10D 1/042; H10D 1/47; H10D 1/716

(57) ABSTRACT

A method for manufacturing a semiconductor device includes: forming a first interconnect structure over a substrate, the first interconnect structure including a first conductive feature; forming a resistor structure over the first conductive feature; forming a second interconnect structure on the resistor structure, the second interconnect structure including two second conductive features which are spaced apart from each other and which are electrically connected to the resistor structure; forming a third interconnect structure on the second interconnect structure, the third interconnect structure including two third conductive features which are spaced apart from each other and which are electrically connected to the two second conductive features, respectively; and forming a capacitor structure over the resistor structure such that the capacitor structure is disposed between the two third conductive features.

### BACKGROUND

Due to rapid growth in the semiconductor technology, semiconductor devices (e.g., logic devices or memory devices) paly important role and are widely applied in various electronic products. In advanced semiconductor manufacturing processes, resistors (such as high-resistance (R) resistors) are introduced in a back-end-of-line (BEOL) process for the formation of an interconnect structure of a semiconductor device (for example, but not limited to, a logic device). The resistors serve as a heat source, which may cause a severe joule heating issue in the interconnect structure. In order to meet application needs, the semiconductor industry is devoted to improve device performance of the semiconductor devices by solving the joule heating issue.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 18B are schematic views illustrating some intermediate stages of the method as depicted in FIGS. 1A and 1B in accordance with some embodiments.

FIGS. 19A and 19B are schematic views illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

In advanced semiconductor manufacturing processes, resistors (such as high-resistance (R) resistors) are elements used in an interconnect structure of a semiconductor device (for example, but not limited to, a logic device). In general, in an interconnect structure of a semiconductor device, some metal lines of each of two metal layers respectively disposed above and below the resistors serve as dummy metal lines without functionality for signal routing. When the semiconductor device is in operation, heat generated from the resistors may not be efficiently spread through the dummy metal lines or other structures (e.g., dielectric layers), and may accumulate near a region at which the resistors are disposed, resulting in a severe joule heating issue. In this case, the region at which the resistors are disposed serves as a local heat source (or a hot block) and has a maximum temperature (Tmax) in the semiconductor device, which may adversely affect device performance (e.g., operation speed) of the semiconductor device. In addition, a current-resistance (IR) loss may occur during operation of the semiconductor device, which may also adversely affect the device performance and reliability of the semiconductor device.

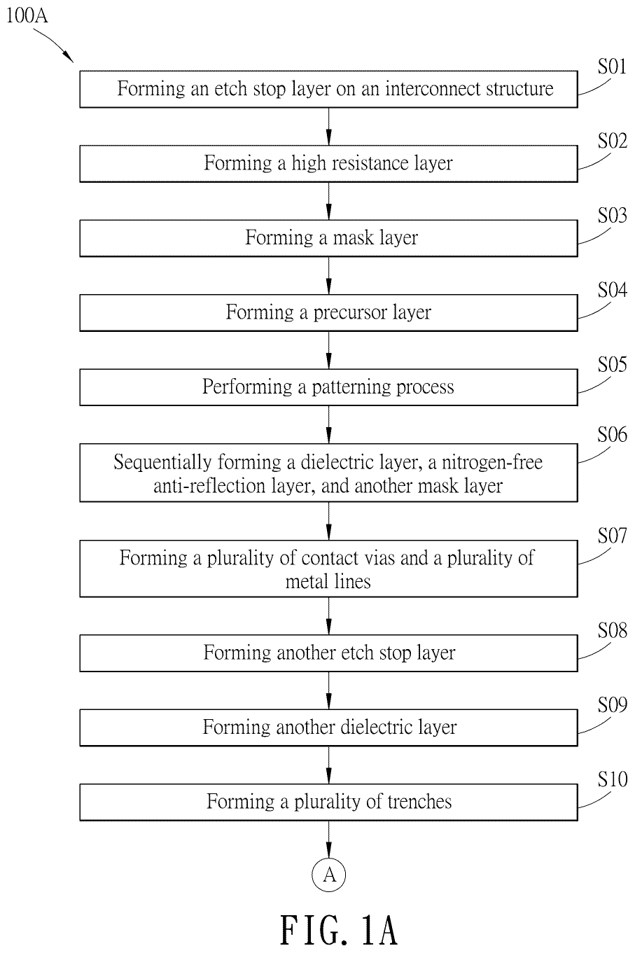

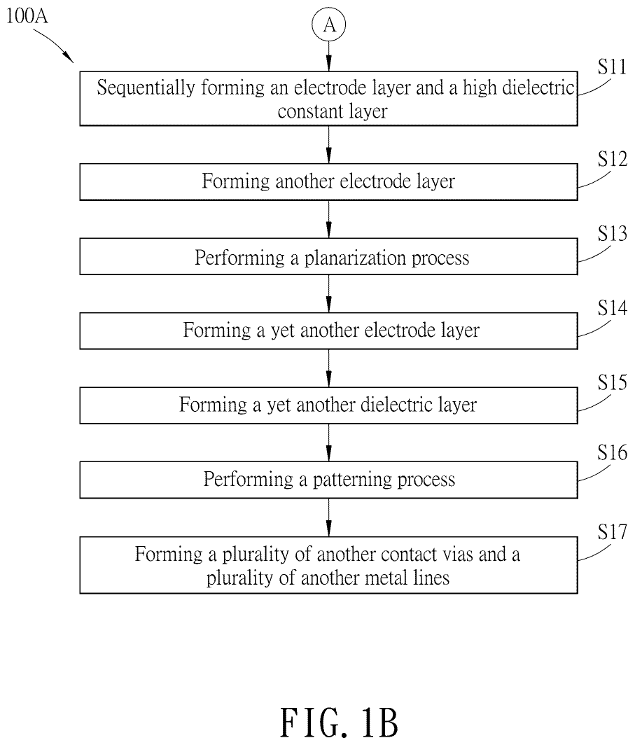

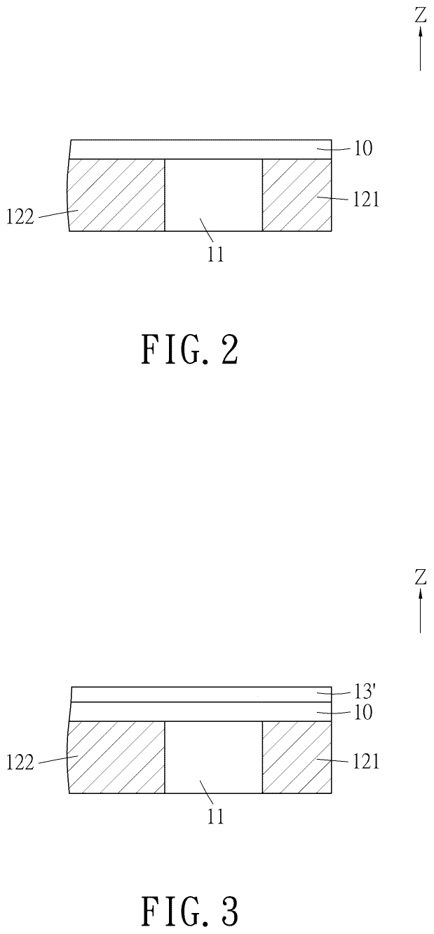

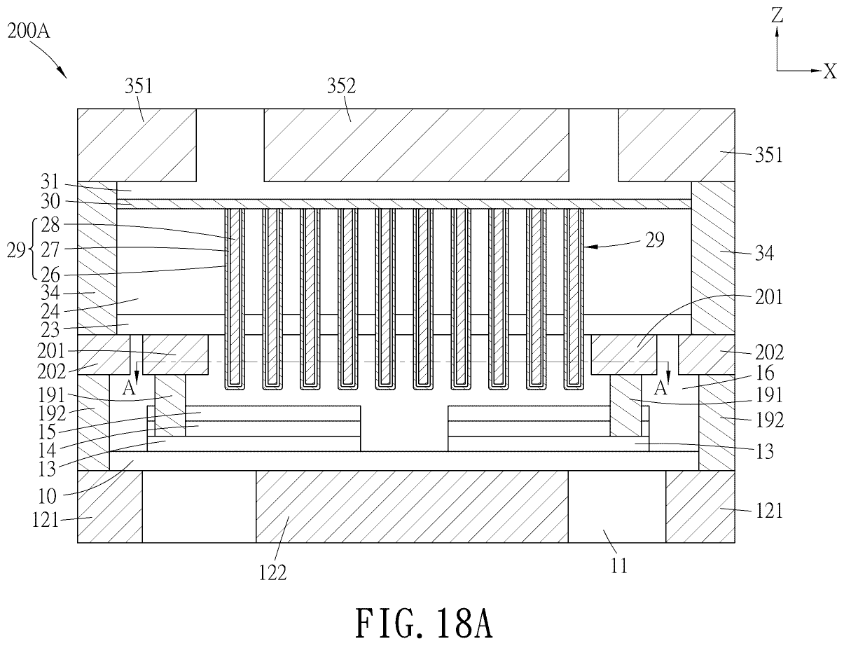

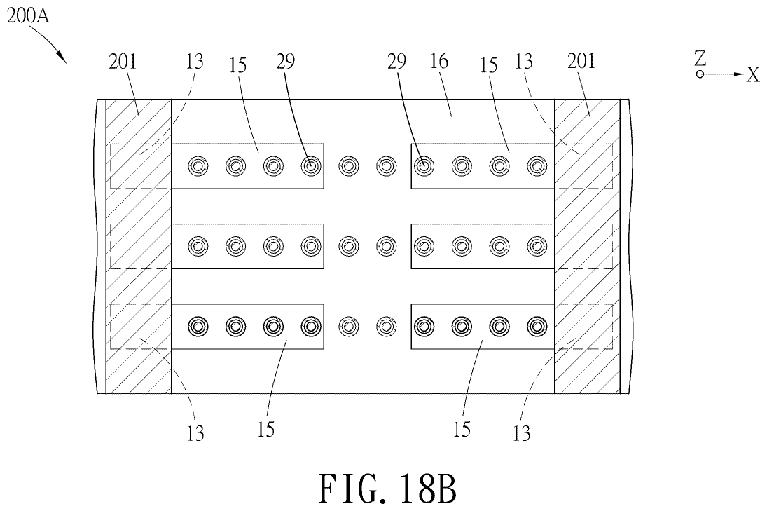

The present disclosure is directed to a semiconductor device and a method for manufacturing the same. FIGS. 1A and 1B are flow diagrams illustrating a method 100A for manufacturing a semiconductor device 200A shown in FIGS. 18A and 18B in accordance with some embodiments. FIGS. 2 to 17 illustrate schematic views of some intermediate stages of the method 100A. Some portions may be omitted in FIGS. 2 to 17 for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step S01, where an etch stop layer 10 is formed on an interconnect structure in a Z direction. The interconnect structure is disposed over a substrate (not shown). In some embodiments, the substrate may be a semiconductor substrate, which may be made of, for example, but not limited to, an elemental semiconductor (e.g., silicon or germanium) or a compound semiconductor (e.g., silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or the like). In some embodiments, the interconnect structure includes a dielectric layer 11 and a plurality of metal lines (i.e., conductive features) 121, 122. In some embodiments, the metal line 122 may be referred to as a dummy metal line (i.e., a dummy conductive feature). The metal lines 121, 122 are disposed in the dielectric layer 11. In some embodiments, the Z direction is perpendicular to a lower surface of the dielectric layer 11.

In some embodiments, the dielectric layer 11 may be made of a low-dielectric constant (k) material, for example, but not limited to, silicon oxide, carbon-doped silicon oxide, silicon oxycarbide, Xerogel, Aerogel, fluorosilicate glass (FSG), amorphous fluorinated carbon, Parylene, polyimide, benzocyclobutene (BCB), or combinations thereof. Other suitable low-k materials for forming the dielectric layer 11 are within the contemplated scope of the present disclosure. In some embodiments, the dielectric layer 11 may be formed by a suitable deposition process, for example, but not limited to, chemical vapor deposition (CVD) or physical vapor deposition (PVD). Other suitable deposition processes for forming the dielectric layer 11 are within the contemplated scope of the present disclosure.

In some embodiments, each of the metal lines 121, 122 may be made of, for example, but not limited to, copper. Other suitable materials for forming each of the metal lines 121 and the dummy metal lines 122 are within the contemplated scope of the present disclosure. It is noted that the metal line 121 may be used for signal routing in the semiconductor device 200A, and the metal line 122 may not be used for signal routing in the semiconductor device 200A.

In some embodiments, the etch stop layer 10 may include, for example, but not limited to, silicon oxide, silicon nitride, aluminum oxide, aluminum nitride, or combinations thereof. Other suitable materials for forming the etch stop layer 10 are within the contemplated scope of the present disclosure. In some embodiments, the etch stop layer 10 may be formed by a suitable deposition process, for example, but not limited to, CVD, PVD, or atomic layer deposition (ALD). Other suitable deposition processes for forming the etch stop layer 10 are within the contemplated scope of the present disclosure.

Referring to FIG. 1A and the example illustrated in FIG. 3, the method 100A then proceeds to step S02, where a high resistance layer 13′ is formed on the etch stop layer 10 opposite to the interconnect structure. In some embodiments, the high resistance layer 13′ may include, for example, but not limited to, titanium nitride, titanium oxide, tantalum nitride, tantalum oxide, silicon nitride, tungsten carbon nitride, boron nitride, zirconium oxide, or combinations thereof. Other suitable materials for forming the high resistance layer 13′ are within the contemplated scope of the present disclosure. In some embodiments, the high resistance layer 13′ may be formed by a suitable deposition process, for example, but not limited to, CVD, PVD, or ALD. Other suitable deposition processes for forming the high resistance layer 13′ are within the contemplated scope of the present disclosure.

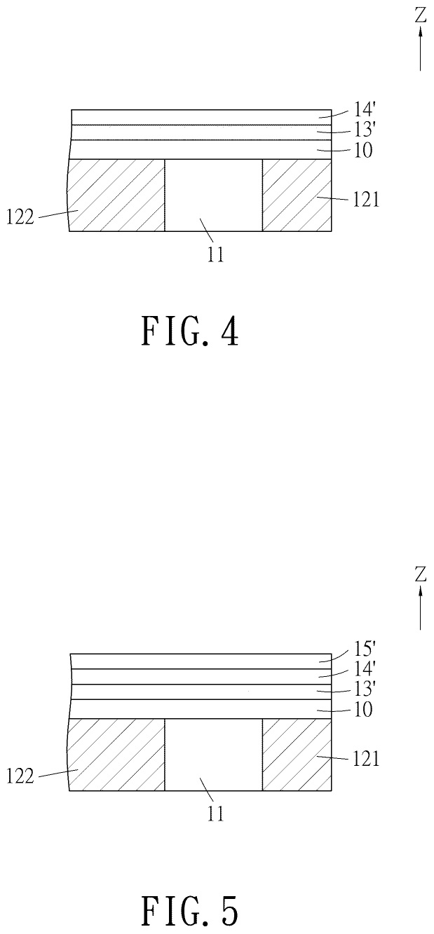

Referring to FIG. 1A and the example illustrated in FIG. 4, the method 100A then proceeds to step S03, where a mask layer 14′ is formed on the high resistance layer 13′ opposite to the etch stop layer 10. In some embodiments, the mask layer 14′ may include, for example, but not limited to, titanium nitride, amorphous silicon, tungsten carbide, or combinations thereof. Other suitable materials for forming the mask layer 14′ are within the contemplated scope of the present disclosure. In some embodiments, the mask layer 14′ and the high resistance layer 13′ may be made of different materials. In some embodiments, the mask layer 14′ may be formed by a suitable deposition process, for example, but not limited to, PVD. Other suitable deposition processes for forming the mask layer 14′ are within the contemplated scope of the present disclosure.

Referring to FIG. 1A and the example illustrated in FIG. 5, the method 100A then proceeds to step S04, where a precursor layer 15′ is formed on the mask layer 14′ opposite to the high resistance layer 13′. In some embodiments, the precursor layer 15′ may include, for example, but not limited to, tetraethoxysilane (TEOS). Other suitable materials for forming the precursor layer 15′ are within the contemplated scope of the present disclosure. In some embodiments, the precursor layer 15′ may be formed by a suitable deposition process, for example, but not limited to, CVD. Other suitable deposition processes for forming the precursor layer 15′ are within the contemplated scope of the present disclosure.

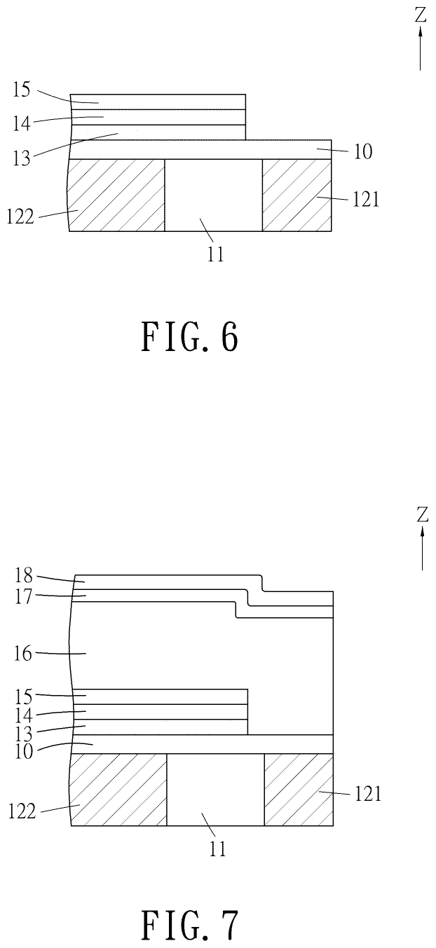

Referring to FIG. 1A and the example illustrated in FIG. 6, the method 100A then proceeds to step S05, where a patterning process is performed on the structure shown in FIG. 5, so that a portion of the precursor layer 15′, a portion of the mask layer 14′, and a portion of the high resistance layer 13′ are removed. The patterning process may be a photolithography process, which includes an etching process. In some embodiments, the photolithography process may include, for example, but not limited to, coating a photoresist (not shown) on the precursor layer 15′, soft-baking the photoresist, exposing the photoresist through a photomask (not shown), post-exposure baking the photoresist, and developing the photoresist, followed by hard-baking the photoresist so as to form a patterned photoresist on the precursor layer 15′. In the etching process, the precursor layer 15′, the mask layer 14′ and the high resistance layer 13′ may be etched by a suitable etching process (for example, but not limited to, dry etching, wet etching, a combination thereof, or other suitable etching processes) using the patterned photoresist as a patterned mask. The patterned photoresist may be removed by, for example, but not limited to, an ashing process or other suitable removal processes after the etching process. Other suitable patterning processes are within the contemplated scope of the present disclosure. After this step, the precursor layer 15′ is formed into a plurality of precursor layer portions 15 (see FIG. 18B), the mask layer 14′ is formed into a plurality of mask layer portions 14 (see FIG. 18B), and the high resistance layer 13′ is formed into a plurality of high resistance resistors 13 (see FIG. 18B). The high resistance resistors 13 cooperate with one another to form a resistor structure. It is noted that one of the precursor layer portions 15, one of the mask layer portions 14, and one of the high resistance resistors 13 are shown in FIG. 6.

Referring to FIG. 1A and the example illustrated in FIG. 7, the method 100A then proceeds to step S06, where a dielectric layer 16, a nitrogen-free anti-reflection layer (NFARL) 17, and a mask layer 18 are sequentially formed on the structure shown in FIG. 6 in the Z direction. Step S06 may include sub-steps (i) to (iii).

In sub-step (i), the dielectric layer 16 is conformally formed on the structure shown in FIG. 6. The material and process for forming the dielectric layer 16 may be the same as or similar to those for forming the dielectric layer 11, and thus details thereof are omitted for the sake of brevity.

In sub-step (ii), the NFARL 17 is conformally formed on the dielectric layer 16 of the previously obtained structure. In some embodiments, the NFARL 17 may include, for example, but not limited to, carbon-doped silicon oxide. Other suitable materials for forming the NFARL 17 are within the contemplated scope of the present disclosure. In some embodiments, the NFARL 17 may be formed by a suitable deposition process, for example, but not limited to, CVD. Other suitable deposition processes for forming the NFARL 17 are within the contemplated scope of the present disclosure.

In sub-step (iii), the mask layer 18 is conformally formed on the NFARL 17 of the previously obtained structure. The material and process for forming the mask layer 18 may be the same as or similar to those for forming the mask layer 14′, and thus details thereof are omitted for the sake of brevity.

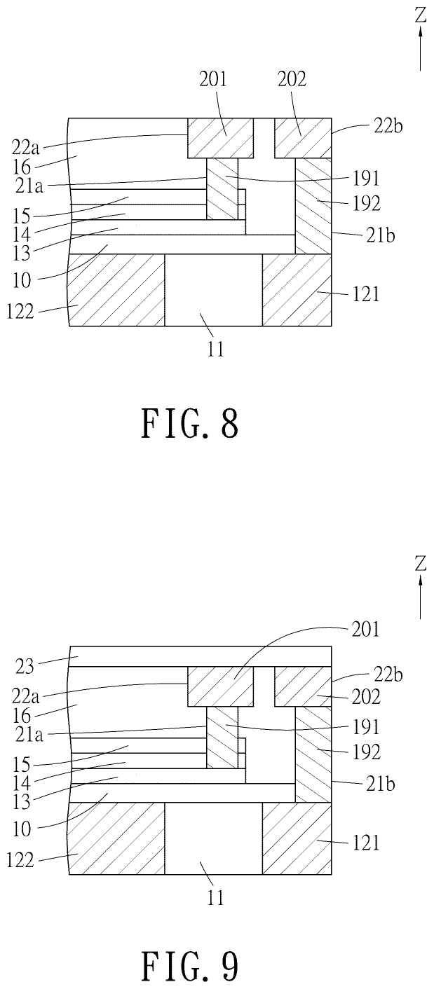

Referring to FIG. 1A and the example illustrated in FIG. 8, the method 100A then proceeds to step S07, where a plurality of contact vias (i.e., conductive features) 191, 192 and a plurality of metal lines (i.e., conductive features) 201, 202 are formed in the dielectric layer 16. Step S07 may include sub-steps (i) to (iii).

In sub-step (i), a patterning process is performed on the structure shown in FIG. 7, so as to form a plurality of via openings 21a, 21b and a plurality of trenches 22a, 22b. Two of the via openings 21a, 21b and two of the trenches 22a, 22b are shown in FIG. 8. In some embodiments, the patterning process may be, for example, but not limited to, a photolithography process (as described in step S05). Other suitable patterning processes are within the contemplated scope of the present disclosure. In some embodiments, each of the trenches 22a, 22b is located at a level higher than that of a corresponding one of the via openings 21a, 21b. In some embodiments, each of the trenches 22a, 22b is in spatial communication with a corresponding one of the via openings 21a, 21b. In some embodiments, each of the trenches 22a, 22b has a width larger than that of a corresponding one of the via openings 21a, 21b. In some embodiments, the via opening 21a penetrates the precursor layer portion 15 and the mask layer portion 14, and terminates at an upper surface of the high resistance resistor 13. In some embodiments, the via opening 21b penetrates the etch stop layer 10 and terminates at an upper surface of the metal line 121.

In sub-step (ii), a conductive material layer for forming the contact vias 191, 192 and the metal lines 201, 202 is formed on the mask layer 18 (see FIG. 7), such that the conductive material layer fills the via openings 21a, 21b and the trenches 22a, 22b. In some embodiments, the conductive material layer may include, for example, but not limited to, copper. Other suitable materials for forming the conductive material layer are within the contemplated scope of the present disclosure. In some embodiments, the conductive material layer may be formed by a suitable deposition process, for example, but not limited to, CVD, PVD, or ALD. Other suitable deposition processes for forming the conductive material layer are within the contemplated scope of the present disclosure.

In sub-step (iii), a planarization process is performed on the structure obtained after sub-step (ii) above to remove an excess portion of the conductive material layer on the mask layer 18, the mask layer 18, and the NFARL 17. In some embodiments, the planarization process may be, for example, but not limited to, a chemical mechanical polishing (CMP) process. Other suitable planarization processes are within the contemplated scope of the present disclosure. In some embodiments, in this sub-step, a portion of the dielectric layer 16 may be removed.

In some embodiments, the contact vias 191, 192 and the metal lines 201, 202 may be formed sequentially. In some embodiments, the contact vias 191, 192 are formed by a single damascene process. Thereafter, the metal lines 201, 202 are formed by another single damascene process.

Referring to FIG. 1A and the example illustrated in FIG. 9, the method 100A then proceeds to step S08, where an etch stop layer 23 is formed on the structure shown in FIG. 8 in the Z direction. The material and process for forming the etch stop layer 23 may be the same as or similar to those for forming the etch stop layer 10, and thus details thereof are omitted for the sake of brevity.

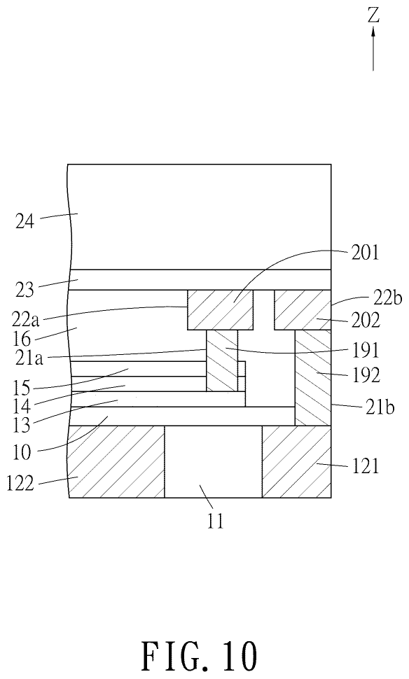

Referring to FIG. 1A and the example illustrated in FIG. 10, the method 100A then proceeds to step S09, where a dielectric layer 24 is formed on the structure shown in FIG. 9 in the Z direction. The material and process for forming the dielectric layer 24 may be the same as or similar to those for forming the dielectric layer 11, and thus details thereof are omitted for the sake of brevity.

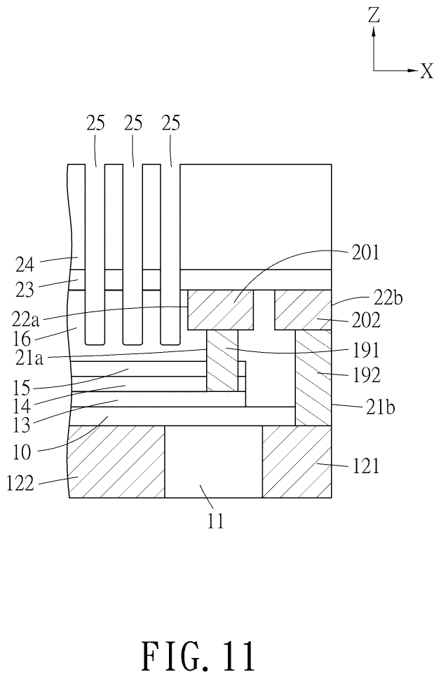

Referring to FIG. 1A and the example illustrated in FIG. 11, the method 100A then proceeds to step S10, where a patterning process is performed to pattern the structure shown in FIG. 10, so as to form a plurality of trenches 25. The patterning process may be, for example, but not limited to, a photolithography process (as described in step S05). Other suitable patterning processes are within the contemplated scope of the present disclosure. In some embodiments, each of the trenches 25 may penetrate the dielectric layer 24 and the etch stop layer 23, and may extend into the dielectric layer 16. In some embodiments, the trenches 25 are spaced apart from one another in an X direction transverse to the Z direction.

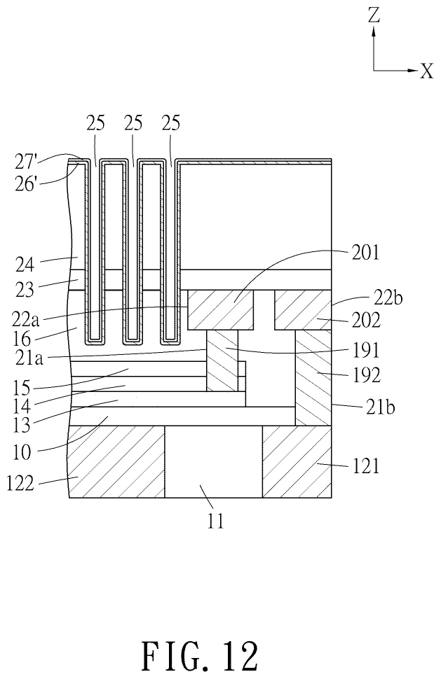

Referring to FIG. 1B and the example illustrated in FIG. 12, the method 100A then proceeds to step S11, where an electrode layer 26′ and a high-dielectric constant (high-k) layer 27′ are sequentially and conformally formed on the structure shown in FIG. 11. Step S11 may include sub-steps (i) and (ii).

In sub-step (i), the electrode layer 26′ is conformally formed on an upper surface of the dielectric layer 24 and in the trenches 25. In some embodiments, the electrode layer 26′ may include, for example, but not limited to, copper, titanium nitride, tungsten, cobalt, aluminum, rhodium, iridium, ruthenium, molybdenum, osmium, silver, gold, or combinations thereof. Other suitable materials for forming the electrode layer 26′ are within the contemplated scope of the present disclosure. In some embodiments, the electrode layer 26′ may be formed by a suitable deposition process, for example, but not limited to, CVD, PVD, ALD, ion beam deposition (IBD), molecular beam epitaxy (MBE), electrochemical plating (ECP), or electrochemical deposition (ECD). Other suitable deposition processes for forming the electrode layer 26′ are within the contemplated scope of the present disclosure.

In sub-step (ii), the high-k layer 27′ is conformally formed on the electrode layer 26′ and in the trenches 25. In some embodiments, the high-k layer 27′ may include, for example, but not limited to, zirconium oxide, hafnium oxide, aluminum oxide, strontium titanate, titanium oxide, barium titanate, barium oxide, cerium oxide, niobium oxide, tantalum oxide, or combinations thereof. Other suitable materials for forming the high-k layer 27′ are within the contemplated scope of the present disclosure. In some embodiments, the high-k layer 27′ may be formed by a suitable deposition process, for example, but not limited to, CVD, PVD, or ALD. Other suitable deposition processes for forming the high-k layer 27′ are within the contemplated scope of the present disclosure.

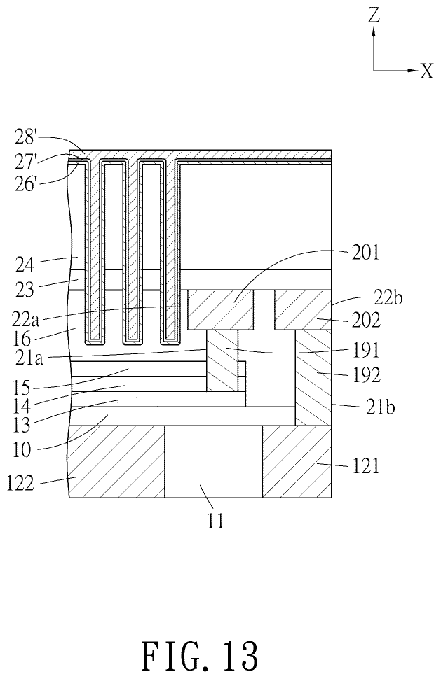

Referring to FIG. 1B and the example illustrated in FIG. 13, the method 100A then proceeds to step S12, where an electrode layer 28′ is formed on the structure shown in FIG. 12 to fill the trenches 25. The material and process for forming the electrode layer 28′ may be the same as or similar to those for forming the electrode layer 26′, and thus details thereof are omitted for the sake of brevity.

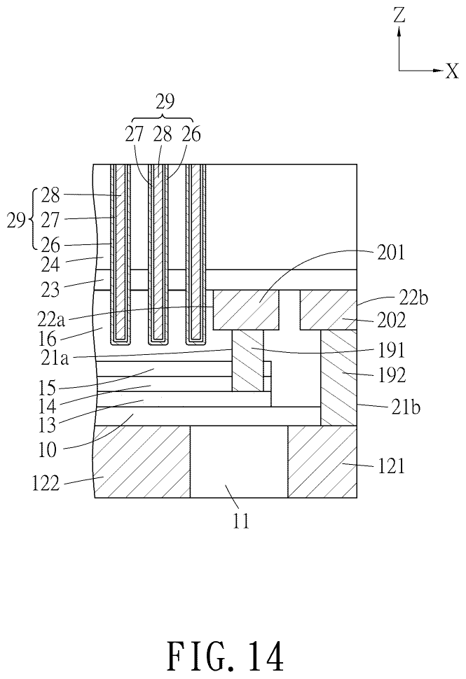

Referring to FIG. 1B and the example illustrated in FIG. 14, the method 100A then proceeds to step S13, where an excess portion of the electrode layer 28′, an excess portion of the high-k layer 27′, and an excess portion of the electrode layer 26′ are removed. Step S13 may be performed by a suitable planarization process, for example, but not limited to, CMP. Other suitable planarization processes are within the contemplated scope of the present disclosure. After this step: the excess portion of the electrode layer 26′ on the upper surface of the dielectric layer 24 is removed and the electrode layer 26′ is formed into a plurality of outer electrodes 26; the excess portion of the high-k layer 27′ on the upper surface of the dielectric layer 24 is removed and the high-k layer 27′ is formed into a plurality of high-k portions 27; and the excess portion of the electrode layer 28′ on the upper surface of the dielectric layer 24 is removed and the electrode layer 28′ is formed into a plurality of inner electrodes 28. In some embodiments, each of the high-k portions 27 surrounds a corresponding one of the inner electrodes 28. In some embodiments, each of the outer electrodes 26 surrounds a corresponding one of the high-k portions 27. In some embodiments, each of the outer electrodes 26, a corresponding one of the high-k portions 27, and a corresponding one of the inner electrodes 28 may cooperate to form a capacitor unit 29 (i.e., a plurality of the capacitor units 29 are formed after this step, and are spaced apart from one another in the X direction). The capacitor units 29 cooperate to form a capacitor structure disposed above the resistor structure. In some embodiments, each of the capacitor units 29 may be referred to as a decoupling capacitor. In some embodiments, each of the capacitor units 29 may have a capacitance density ranging from about 200 fF/um² to about 400 fF/um².

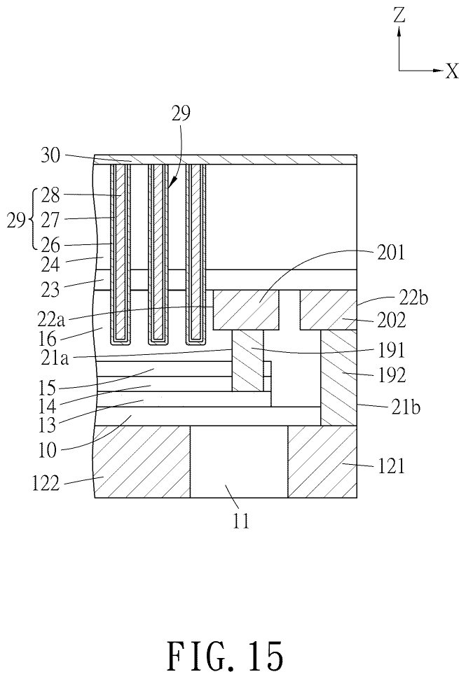

Referring to FIG. 1B and the example illustrated in FIG. 15, the method 100A then proceeds to step S14, where an electrode layer 30 is formed on the structure shown in FIG. 14. The material and process for forming the electrode layer 30 may be the same as or similar to those for forming the electrode layer 26′, and thus details thereof are omitted for the sake of brevity. In this case, the electrode layer 30 is electrically connected to the capacitor units 29. In some embodiments, after this step, a patterning process (e.g., the photolithography process (as described in step S05) or other suitable patterning processes) may be performed to pattern the electrode layer 30, so as to form the electrode layer 30 into a plurality of upper electrodes (not shown) spaced apart from each other. In this case, each of the upper electrodes is electrically connected to corresponding one(s) of the capacitor units 29.

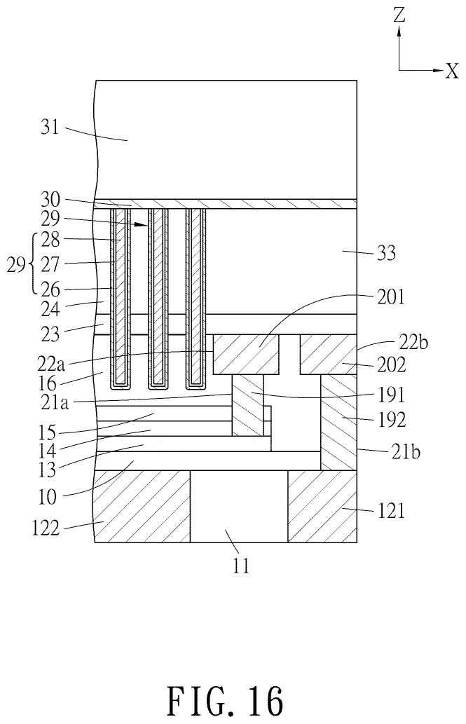

Referring to FIG. 1B and the example illustrated in FIG. 16, the method 100A then proceeds to step S15, where a dielectric layer 31 is formed on the structure shown in FIG. 15. The material and process for forming the dielectric layer 31 may be the same as or similar to those for forming the dielectric layer 11, and thus details thereof are omitted for the sake of brevity.

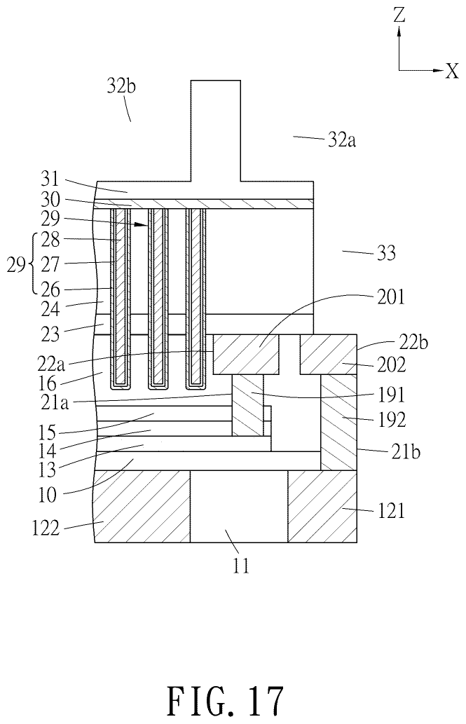

Referring to FIG. 1B and the example illustrated in FIG. 17, the method 100A then proceeds to step S16, where a patterning process is performed on the structure shown in FIG. 16, so as to form a plurality of trenches 32a, 32b and a plurality of via openings 33. Two of the trenches 32a, 32b and one of the via openings 33 are shown in FIG. 17. In some embodiments, the patterning process may be, for example, but not limited to, a photolithography process (as described in step S05). Other suitable patterning processes are within the contemplated scope of the present disclosure. In some embodiments, each of the trenches 32a, 32b may extend into the dielectric layer 31. In some embodiments, each of the via openings 33 may penetrate the dielectric layer 31, the electrode layer 30, the dielectric layer 24 and the etch stop layer 23, and may terminate at an upper surface of a corresponding one of the metal lines 202. In some embodiments, each of the trenches 32a, 32b is located at a level higher than that of a corresponding one of the via openings 33. In some embodiments, each of the via openings 33 is in spatial communication with a corresponding one of the trenches 32a. In some embodiments, each of the trenches 32a, 32b has a width larger than that of a corresponding one of the via openings 33.

Referring to FIG. 1B and the example illustrated in FIGS. 18A and 18B, the method 100A then proceeds to step S17, where a plurality of contact vias (i.e., conductive features) 34 and a plurality of metal lines (i.e., conductive features) 351, 352 are formed. FIG. 18B illustrates a planar schematic view taken along line A-A of FIG. 18A. Step S17 may include sub-steps (i) and (ii).

In sub-step (i), a conductive material layer for forming the contact vias 34 and the metal lines 351, 352 is formed on the structure shown in FIG. 17, such that the conductive material layer fills the via openings 33 and the trenches 32a, 32b. In some embodiments, the conductive material layer may include, for example, but not limited to, copper. Other suitable materials for forming the conductive material layer are within the contemplated scope of the present disclosure. In some embodiments, the conductive material layer may be formed by a suitable deposition process, for example, but not limited to, CVD, PVD, or ALD. Other suitable deposition processes for forming the conductive material layer are within the contemplated scope of the present disclosure.

In sub-step (ii), a planarization process (e.g., CMP or other suitable planarization processes) is performed on the structure obtained after sub-step (i) above to remove an excess portion of the conductive material layer, so as to form the contact vias 34 and the metal lines 351, 352. In some embodiments, the metal line 352 may be referred to as a dummy metal line (i.e., a dummy conductive feature without functionality for signal routing), and is located at a level higher than that of a respective one of the capacitor units 29. In some embodiments, each of the contact vias 34 is disposed between and connected to a corresponding one of the metal lines 202 and a corresponding one of the metal lines 351. In some embodiments, when the electrode layer 30 is formed into the upper electrodes, each of the upper electrodes is disposed between and connected to two corresponding ones of the contact vias 34.

In some embodiments, the contact vias 34 and the metal lines 351, 352 may be formed sequentially. In some embodiments, the contact vias 34 are formed by a single damascene process. Thereafter, the metal lines 351, 352 are formed by another single damascene process.

After step S17, the semiconductor device 200A is obtained. In some embodiments, the capacitor units 29 are located between the metal line 122 and the metal line 352, each of which serves as a dummy metal line. When the semiconductor device 200A is in operation, heat generated from the high resistance resistors 13 may be efficiently spread through the capacitor units 29, which is conducive to reducing heat accumulation near the high resistance resistors 13 (Tmax may reduce from about 10% to about 15%) and to preventing severe joule heating. In other words, the capacitor units 29 serve as heat pipes and provide heat transport path for the heat generated from the high resistance resistors 13. In addition, by having the capacitor units 29, a current-resistance (IR) loss may be reduced in the semiconductor device 200A, which is beneficial to improving device performance (e.g., an increase of speed gain ranging from about 1% to about 2%) of the semiconductor device 200A.

In some embodiments, in step S10, each of the trenches 25 (see FIG. 11) may penetrate a plurality of dielectric layers, and a number of the dielectric layers may range from about 2 to about 7.

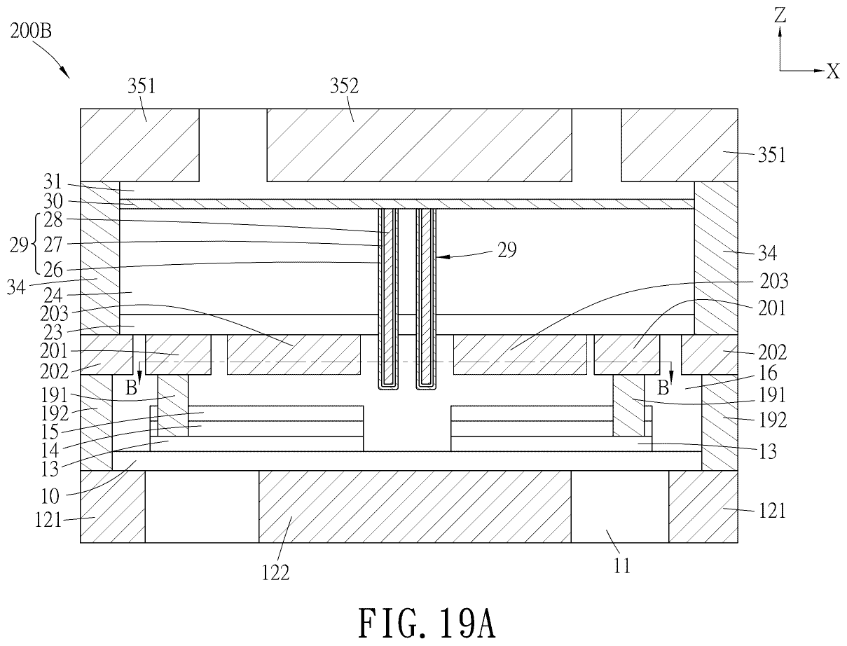

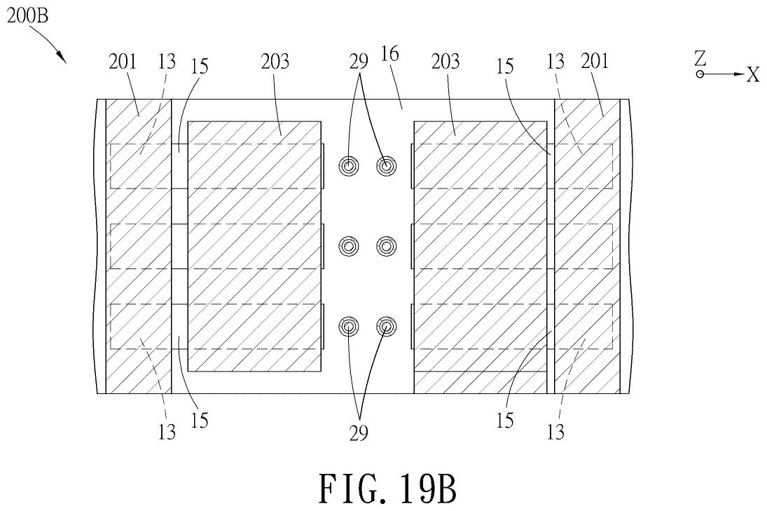

FIGS. 19A and 19B illustrate schematic views of a semiconductor device 200B. FIG. 19B illustrates a planar schematic view taken along line B-B of FIG. 19A. The structure of the semiconductor device 200B is similar to that of the semiconductor device 200A, except that, in the semiconductor device 200B, a density of the capacitor units 29 is lower than that of the capacitor units 29 in the semiconductor device 200A. In this case, pairs of the capacitor units 29 are spaced apart from one another in a Y direction transverse to the X direction and the Z direction, and each pair of the capacitor units 29 is disposed between two adjacent ones of metal lines (i.e., conductive features) 203, which are disposed over corresponding ones of the high resistance resistors 13. In some embodiments, each of the metal lines 203 may be a dummy metal line (i.e., a dummy conductive feature without signal routing function). In some embodiments, a projection of each pair of the capacitor units 29 on the etch stop layer 10 is disposed between two projections of two adjacent ones of the high resistance resistors 13 on the etch stop layer 10 (see FIG. 19A), in which the two adjacent ones of the high resistance resistors 13 are disposed opposite to each other in the X direction with respect to the each pair of the capacitor units 29.

In a semiconductor device of this disclosure, at least one capacitor unit is disposed at a region above a high resistance resistor. The at least one capacitor unit may include an outer electrode, a high-k portion, and an inner electrode, where the high-k portion surrounds the inner electrode and the outer electrode surrounds the high-k portion. When the semiconductor device of this disclosure is in operation, heat generated from the high resistance resistor can be efficiently spread through the at least one capacitor unit, so that heat accumulation is reduced near the high resistance resistor and severe joule heating is prevented. In addition, disposition of the at least one capacitor unit is beneficial for reducing IR loss of the semiconductor device. Therefore, by having the at least one capacitor unit, device performance (e.g., operation speed) and reliability of the semiconductor device can be improved.

In accordance with some embodiments of the present disclosure, a method for manufacturing a semiconductor device includes: forming a first interconnect structure over a substrate, the first interconnect structure including a first conductive feature; forming a resistor structure over the first conductive feature; forming a second interconnect structure on the resistor structure, the second interconnect structure including two second conductive features which are spaced apart from each other and which are electrically connected to the resistor structure; forming a third interconnect structure on the second interconnect structure, the third interconnect structure including two third conductive features which are spaced apart from each other and which are electrically connected to the two second conductive features, respectively; and forming a capacitor structure over the resistor structure such that the capacitor structure is disposed between the two third conductive features.

In accordance with some embodiments of the present disclosure, the method for manufacturing the semiconductor device further includes: forming a first electrode layer on the capacitor structure such that the capacitor structure is electrically connected to the first electrode layer.

In accordance with some embodiments of the present disclosure, the capacitor structure includes a capacitor unit which extends from the first electrode layer toward the resistor structure in a first direction perpendicular to the first electrode layer.

In accordance with some embodiments of the present disclosure, the capacitor unit includes an outer electrode, a high-dielectric constant portion surrounded by the outer electrode, and an inner electrode surrounded by the high-dielectric constant portion.

In accordance with some embodiments of the present disclosure, the capacitor unit is formed by forming a dielectric layer over the resistor structure; patterning the dielectric layer to form a trench which extends toward the resistor structure in the first direction; forming a second electrode layer on the dielectric layer and in the trench; forming a high-dielectric constant layer on the second electrode layer and in the trench; forming a third electrode layer on the high-dielectric constant layer such that the third electrode layer fills the trench; and removing an excess portion of the third electrode layer, an excess portion of the high-dielectric constant layer, and an excess portion of the second electrode layer, so that the third electrode layer is formed into the inner electrode, the high-dielectric constant layer is formed into the high-dielectric constant portion, and the second electrode layer is formed into the outer electrode.

In accordance with some embodiments of the present disclosure, the method for manufacturing the semiconductor device further includes: before formation of the dielectric layer, forming an etch stop layer on the third interconnect structure, so that the trench penetrates through the etch stop layer after the dielectric layer is patterned to form the trench.

In accordance with some embodiments of the present disclosure, each of the first electrode layer, the second electrode layer, and the third electrode layer includes copper, titanium nitride, tungsten, cobalt, aluminum, rhodium, iridium, ruthenium, molybdenum, osmium, silver, gold, or combinations thereof.

In accordance with some embodiments of the present disclosure, the high-dielectric constant layer includes zirconium oxide, hafnium oxide, aluminum oxide, strontium titanate, titanium oxide, barium titanate, barium oxide, cerium oxide, niobium oxide, tantalum oxide, or combinations thereof.

In accordance with some embodiments of the present disclosure, the third interconnect structure further includes two fourth conductive features disposed between the two third conductive features and over the resistor structure. The two fourth conductive features are spaced apart from each other in a second direction perpendicular to the first direction. The capacitor unit is formed between the two fourth conductive features.

In accordance with some embodiments of the present disclosure, the method for manufacturing the semiconductor device further includes: forming an etch stop layer between the first interconnect structure and the capacitor structure.

In accordance with some embodiments of the present disclosure, the resistor structure includes two resistors which are spaced apart from each other in the second direction and which are disposed on the etch stop layer, and a projection of the capacitor unit on the etch stop layer is disposed between two projections of the two resistors on the etch stop layer.

In accordance with some embodiments of the present disclosure, the capacitor structure includes a plurality of capacitor units which are formed between the two third conductive features and which are spaced apart from each other.

In accordance with some embodiments of the present disclosure, the first electrode layer is formed with a plurality of upper electrodes spaced apart from each other, and each of the upper electrodes is electrically connected to corresponding ones of the capacitor units.

In accordance with some embodiments of the present disclosure, a method for manufacturing a semiconductor device includes: forming a first interconnect structure over a substrate, the first interconnect structure including a first conductive feature; forming a resistor structure over the first conductive feature; forming a second interconnect structure on the resistor structure, the second interconnect structure including two second conductive features which are spaced apart from each other and which are electrically connected to the resistor structure; forming a third interconnect structure on the second interconnect structure, the third interconnect structure including two third conductive features which are spaced apart from each other and which are electrically connected to the two second conductive features, respectively; forming a capacitor structure over the resistor structure such that the capacitor structure is disposed between the two third conductive features; and forming a fourth interconnect structure on the third interconnect structure, the fourth interconnect structure including two fourth conductive features which are spaced apart from each other and which are electrically connected to the two third conductive features, respectively.

In accordance with some embodiments of the present disclosure, the method for manufacturing the semiconductor device includes: forming a first electrode layer on the capacitor structure such that the first electrode layer is disposed between the two fourth conductive features and such that the first electrode layer is electrically connected to the capacitor structure and the two fourth conductive features.

In accordance with some embodiments of the present disclosure, the third interconnect structure further includes two fifth conductive features which are disposed between the two third conductive features and over the resistor structure. The two fifth conductive features are spaced apart from each other. The capacitor structure is formed between the two fifth conductive features. Each of the first conductive feature and the two fifth conductive features serves as a dummy metal line without signal routing function.

In accordance with some embodiments of the present disclosure, a semiconductor device includes a substrate, a first interconnect structure, a resistor structure, a second interconnect structure, a third interconnect structure, and a capacitor structure. The first interconnect structure is disposed over a substrate and includes a first conductive feature. The resistor structure is disposed over the first conductive feature. The second interconnect structure is disposed on the resistor structure, and includes two second conductive features which are spaced apart from each other and which are electrically connected to the resistor structure. The third interconnect structure is disposed on the second interconnect structure, and includes two third conductive features which are spaced apart from each other and which are electrically connected to the two second conductive features, respectively. The capacitor structure is disposed over the resistor structure and between the two third conductive features.

In accordance with some embodiments of the present disclosure, the semiconductor device further includes an electrode layer which is disposed on and electrically connected to the capacitor structure.

In accordance with some embodiments of the present disclosure, the capacitor structure includes a capacitor unit which extends from the electrode layer toward the resistor structure in a first direction perpendicular to the electrode layer.

In accordance with some embodiments of the present disclosure, the third interconnect structure further includes two fourth conductive features which are disposed between the two third conductive features and over the resistor structure. The two fourth conductive features are spaced apart from each other in a second direction perpendicular to the first direction. The capacitor unit is disposed between the two fourth conductive features.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a first interconnect structure over a substrate, the first interconnect structure including a first conductive feature;
forming a resistor structure over the first conductive feature;
forming a second interconnect structure on the resistor structure, the second interconnect structure including two second conductive features which are spaced apart from each other and which are electrically connected to the resistor structure;
forming a third interconnect structure on the second interconnect structure, the third interconnect structure including two third conductive features which are spaced apart from each other and which are electrically connected to the two second conductive features, respectively; and
forming a capacitor structure over the resistor structure such that the capacitor structure is disposed between the two third conductive features.

2. The method as claimed in claim 1, further comprising forming a first electrode layer on the capacitor structure such that the capacitor structure is electrically connected to the first electrode layer.

3. The method as claimed in claim 2, wherein the capacitor structure includes a capacitor unit which extends from the first electrode layer toward the resistor structure in a first direction perpendicular to the first electrode layer.

4. The method as claimed in claim 3, wherein the capacitor unit includes an outer electrode, a high-dielectric constant portion surrounded by the outer electrode, and an inner electrode surrounded by the high-dielectric constant portion.

5. The method as claimed in claim 4, wherein the capacitor unit is formed by
forming a dielectric layer over the resistor structure;
patterning the dielectric layer to form a trench which extends toward the resistor structure in the first direction;
forming a second electrode layer on the dielectric layer and in the trench;
forming a high-dielectric constant layer on the second electrode layer and in the trench;
forming a third electrode layer on the high-dielectric constant layer such that the third electrode layer fills the trench; and
removing an excess portion of the third electrode layer, an excess portion of the high-dielectric constant layer, and an excess portion of the second electrode layer, so that the third electrode layer is formed into the inner electrode, the high-dielectric constant layer is formed into the high-dielectric constant portion, and the second electrode layer is formed into the outer electrode.

6. The method as claimed in claim 5, further comprising, before formation of the dielectric layer, forming an etch stop layer on the third interconnect structure, so that the trench penetrates through the etch stop layer after the dielectric layer is patterned to form the trench.

7. The method as claimed in claim 5, wherein each of the first electrode layer, the second electrode layer, and the third electrode layer includes copper, titanium nitride, tungsten, cobalt, aluminum, rhodium, iridium, ruthenium, molybdenum, osmium, silver, gold, or combinations thereof.

8. The method as claimed in claim 5, wherein the high-dielectric constant layer includes zirconium oxide, hafnium oxide, aluminum oxide, strontium titanate, titanium oxide, barium titanate, barium oxide, cerium oxide, niobium oxide, tantalum oxide, or combinations thereof.

9. The method as claimed in claim 3, wherein
the third interconnect structure further includes two fourth conductive features disposed between the two third conductive features and over the resistor structure, the two fourth conductive features being spaced apart from each other in a second direction perpendicular to the first direction; and
the capacitor unit is formed between the two fourth conductive features.

10. The method as claimed in claim 9, further comprising forming an etch stop layer between the first interconnect structure and the capacitor structure.

11. The method as claimed in claim 10, wherein
the resistor structure includes two resistors which are spaced apart from each other in the second direction and which are disposed on the etch stop layer, and
a projection of the capacitor unit on the etch stop layer is disposed between two projections of the two resistors on the etch stop layer.

12. The method as claimed in claim 2, wherein the capacitor structure includes a plurality of capacitor units which are formed between the two third conductive features and which are spaced apart from each other.

13. The method as claimed in claim 12, wherein the first electrode layer is formed with a plurality of upper electrodes spaced apart from each other, each of the upper electrodes being electrically connected to corresponding ones of the capacitor units.

14. A method for manufacturing a semiconductor device, comprising:
forming a first interconnect structure over a substrate, the first interconnect structure including a first conductive feature;
forming a resistor structure over the first conductive feature;
forming a second interconnect structure on the resistor structure, the second interconnect structure including two second conductive features which are spaced apart from each other and which are electrically connected to the resistor structure;
forming a third interconnect structure on the second interconnect structure, the third interconnect structure including two third conductive features which are spaced apart from each other and which are electrically connected to the two second conductive features, respectively;
forming a capacitor structure over the resistor structure such that the capacitor structure is disposed between the two third conductive features; and
forming a fourth interconnect structure on the third interconnect structure, the fourth interconnect structure including two fourth conductive features which are spaced apart from each other and which are electrically connected to the two third conductive features, respectively.

15. The method as claimed in claim 14, further comprising forming a first electrode layer on the capacitor structure such that the first electrode layer is disposed between the two fourth conductive features and such that the first electrode layer is electrically connected to the capacitor structure and the two fourth conductive features.

16. The method as claimed in claim 14, wherein
the third interconnect structure further includes two fifth conductive features disposed between the two third conductive features and over the resistor structure, the two fifth conductive features being spaced apart from each other;
the capacitor structure is formed between the two fifth conductive features; and
each of the first conductive feature and the two fifth conductive features serves as a dummy metal line without signal routing function.

17. A semiconductor device, comprising:
a substrate;
a first interconnect structure disposed over a substrate and including a first conductive feature;
a resistor structure disposed over the first conductive feature;
a second interconnect structure disposed on the resistor structure, and including two second conductive features which are spaced apart from each other and which are electrically connected to the resistor structure;
a third interconnect structure disposed on the second interconnect structure, and including two third conductive features which are spaced apart from each other and which are electrically connected to the two second conductive features, respectively; and
a capacitor structure disposed over the resistor structure and between the two third conductive features.

18. The semiconductor device as claimed in claim 17, further comprising an electrode layer disposed on and electrically connected to the capacitor structure.

19. The semiconductor device as claimed in claim 18, wherein the capacitor structure includes a capacitor unit which extends from the electrode layer toward the resistor structure in a first direction perpendicular to the electrode layer.

20. The semiconductor device as claimed in claim 19, wherein
the third interconnect structure further includes two fourth conductive features disposed between the two third conductive features and over the resistor structure, the two fourth conductive features being spaced apart from each other in a second direction perpendicular to the first direction; and
the capacitor unit is disposed between the two fourth conductive features.
